(19) United States
(12) Patent Application Publication
(10) Pub. No.: US 2017/0293230 A1
(43) Pub. Date: Oct. 12, 2017

(54) Adjustment and Design Method of Illumination System Matched with Multiple Objective Lenses in Extreme Ultraviolet Lithography Machine

(71) Applicants: Ping Liang, Beijing (CN); Jian Yang, Beijing (CN); Yongtian Wang, Beijing (CN); Wenbo Wu, Beijing (CN); Yue Liu, Beijing (CN); Jin Xue, Beijing (CN); Lei Chen, Beijing (CN); Weijian Cong, Beijing (CN)

(72) Inventors: Ping Liang, Beijing (CN); Jian Yang, Beijing (CN); Yongtian Wang, Beijing (CN); Wenbo Wu, Beijing (CN); Yue Liu, Beijing (CN); Jin Xue, Beijing (CN); Lei Chen, Beijing (CN); Weijian Cong, Beijing (CN)

(21) Appl. No.: 15/093,843

(22) Filed: Apr. 8, 2016

(51) Int. Cl. G03F 7/20; G02B 27/00; G02B 3/00; G02B 19/00; G02B 13/16; G02B 13/14; G02B 5/09; G02B 5/00; G02B 13/00

(52) U.S. Cl. CPC G03F 7/70141; G02B 5/005; G02B 27/0012; G02B 3/0056; G02B 13/0095; G02B 13/16; G02B 13/143; G02B 5/09; G02B 19/0028; G02B 19/0095

(57) ABSTRACT

Provided in the present invention is an adjustment and design method of an illumination system matched with multiple objective lenses in an extreme ultraviolet lithography machine; the illumination system to which the method is applied comprises a light source, a collection lens, a field compound eye, a pupil compound eye and a relay lens group; the method specifically comprises the steps: before a projection objective lens of an extreme ultraviolet lithography machine is replaced, calculating aperture angles of emergent ray of a relay lens A on a meridian plane and a sagittal plane by means of ray tracing; after the projection objective lens of the extreme ultraviolet lithography machine is replaced, taking out a central point of a exit pupil plane as an object point for ray tracing; adjusting inclination angles and positions of the relay lens A and a relay lens B, and adjusting inclination angles of central compound eye units of the pupil compound eye and the field compound eye, till an image plane of a current illumination system approximates to an arc-shaped image plane corresponding to the projection objective lens. By adjusting the illumination system on the basis of the adjustment method of the present invention, an illumination system matched with the projection objective lens system can be obtained, which dramatically reduces the cost of designing a projection lithography machine.

### REFERENCE TO RELATED APPLICATIONS

This application claims the benefit of the filing date of China Patent Application Serial No. 201310244882.1 filed on Jun. 19, 2013 and the filing date of PCT Patent Application Serial No. PCT/CN2014/000598 filed on Jun. 18th, 2014, entitled “Adjustment and Design Method of Illumination System Matched with Multiple Objective Lenses in Extreme Ultraviolet Lithography Machine”. The teachings of the entire referenced applications are incorporated herein by reference.

### TECHNICAL FIELD

The present invention relates to an adjustment and design method of an illumination system matched with multiple objective lenses in an extreme ultraviolet lithography machine, belonging to the technical field of lithographic illumination design.

### BACKGROUND

Extreme ultraviolet lithography (EUVL) is a lithography technique that takes the EUV ray of the wavelength of 11-14 nm as an exposure light source, and is applicable to mass production of an integrated circuit with a characteristic dimension of 22 nm and a smaller characteristic dimension. The core component of a projection lighography machine is a projection exposure optical system, and the most important parts of this system are an illumination system and a projection objective lens system. The major function of the illumination system is providing uniform illumination for a mask plane, controlling exposure dose and achieving an off-axis illumination mode. As an important component part of the lithography machine, the illumination system is of critical importance to the improvement of the performance of the whole lithography machine. Therefore, designing the illumination system is the important step of completing the whole projection exposure system.

The illumination system in the projection lithography machine in industrialization is generally made up of parts such as a light source, a collection lens, double rows of compound eyes and a relay lens group. In the design process of the illumination system for the specified projection objective lens, two requirements need to be met: firstly, the exit pupil of the illumination system needs to coincide with the entrance pupil of the projection objective lens; secondly, the dimension and position of the image plane of the illumination system, i.e. the illuminating plane, need to be identical with those of the object plane of projection objective lens. However, in order to further reduce the characteristic dimension, the numerical aperture of the projection objective lens will constantly increase, and its corresponding entrance pupil parameter will also change, with the result that the illumination system matched with the projection objective lens needs to be redesigned. Obviously, using a new component will increase the manufacturing cost greatly, and redesigning a new illumination system will also consume much labor and material. Therefore, it is necessary to develop a method, using the method, on the basis of an initial illumination system; a set of multi-illumination system can be obtained by changing the position of the component, thereby providing illumination for the multiple different objective lens systems.

### SUMMARY OF THE INVENTION

The present invention aims to provide an adjustment and design method of an illumination system matched with multiple objective lenses in an extreme ultraviolet lithography machine. Adjusting the illumination system by the method, enables the illumination system to provide satisfactory illumination for a series of projection objective lenses having the same exposure view field, thereby greatly reducing the manufacturing cost of the extreme ultraviolet lithography machine.

The technical solution for implementing the present invention is as follows:

In an adjustment and design method of an illumination system matched with multiple objective lenses in an extreme ultraviolet lithography machine, the illumination system to which the method is applicable comprises a light source, a collection lens, a field compound eye, a pupil compound eye and a relay lens group; meanwhile, the first relay lens in the relay lens group, through which emergent ray from the light source passes, is defined as a relay lens A, the second relay lens, through which the emergent ray passes, is defined as a relay lens B, the method specifically comprises the steps:

before a projection objective lens of the extreme ultraviolet lithography machine is replaced:

step 101, disposing an aperture diaphragm on an arc-shaped image plane of the illumination system, and unifying the size of the aperture diaphragm and the size of the arc-shaped image plane;

step 102, taking a central point of an exit pupil plane of the illumination system as an object point for ray tracing, and calculating aperture angles of emergent ray of the relay lens A on a meridian plane and a sagittal plane respectively.

after the projection objective lens of the extreme ultraviolet lithography machine is replaced:

step 103, obtaining related parameters of the projection objective lens in the current extreme ultraviolet lithography machine, wherein the related parameters include the size of the arc-shaped image plane, the incidence angle of primary ray on the arc-shaped image plane and the numerical aperture on the arc-shaped image plane;

step 104, calculating the exit pupil plane according to the related parameters, and taking a central point of the exit pupil plane as an object point for ray tracing;

step 105, adjusting the inclination angle of the relay lens A, in order to compensate for the changes of the magnifying power of the field compound eye that results from subsequent adjustment in the illumination system; and adjusting the inclination angle of the relay lens B, in order to compensate for the changes of a central angle corresponding to an arc-shaped light beam that occur due to subsequent adjustment during the process of propagation;

step 106, adjusting the position of the relay lens A, to enable the aperture angles of the emergent light beam of the relay lens A on the meridian plane and the sagittal plane to be respectively equal to the aperture angles calculated in the step 102;

step 107, adjusting the position of the relay lens B, so that an exit pupil center, after passing through the relay lens B and the relay lens A, is imaged on a central compound eye unit of the pupil compound eye, with the two conditions below being met: 1, the center of a light spot on the central compound eye unit of the pupil compound eye and the center of the compound eye unit coincide, and 2, the light beam that is incident on the central compound eye unit of the pupil compound eye can be reflected into the field compound eye by the compound eye unit;

step 108, adjusting the inclination angles of the central compound eye units on the pupil compound eye and the field compound eye, so that the light beam, after passing through the central compound eye unit of the pupil compound eye, can be reflected by the central compound eye unit of the field compound eye, and the light beam, which is reflected by the central compound eye unit of the field compound eye, is perpendicularly incident into the collection lens and then converges at the position of the light source;

step 109, judging whether the image plane of the current illumination system approximates to the arc-shaped image plane obtained in the step 103 or not, and if so, calculating the coordinates and inclination angles of all the compound eye units in the field compound eye and the pupil compound eye, and adjusting all the compound eye units according to the calculated coordinates and inclination angles, so as to complete the adjustment of the illumination system; and if not, sequentially repeating the steps 105 to 108 until the requirement is satisfied.

Beneficial Effect

Firstly, the present invention adjusts the illumination system, to provide satisfactory illumination for a series of projection objective lens systems having the same exposure view field; therefore, after the projection objective lens of the extreme ultraviolet lithography machine is replaced, the illumination system is adjusted on the basis of the adjusting method of the present invention, so that in the case that the corresponding illumination system does not need to be replaced, an illumination system matched with the projection objective lens system can be obtained, thus the cost of designing the extreme ultraviolet lithography machine is dramatically reduced.

Secondly, the adjustment method of the illumination system of the present invention only needs to adjust the position of the components in the illumination system according to the related parameters of the projection objective lens, and it does not adopt any new component, which greatly reduces the costs of designing and manufacturing the extreme ultra-violet lithography machine, and shortens R&D cycle.

### BRIEF DESCRIPTION OF THE DRAWINGS

FIG. 1 is a diagrammatic illustration of the structure of the optical system in an extreme ultraviolet lithography machine.

FIG. 2 is a flowchart illustrating an adjustment and design method of the present invention.

FIG. 3 is a diagrammatic illustration of an arc-shaped image plane of an illumination system.

FIG. 4 is a diagrammatic illustration of the structure of a collection lens.

### DETAILED DESCRIPTION OF THE INVENTION

The invention is now described in detail by way of embodiments with reference to the accompanying drawings.

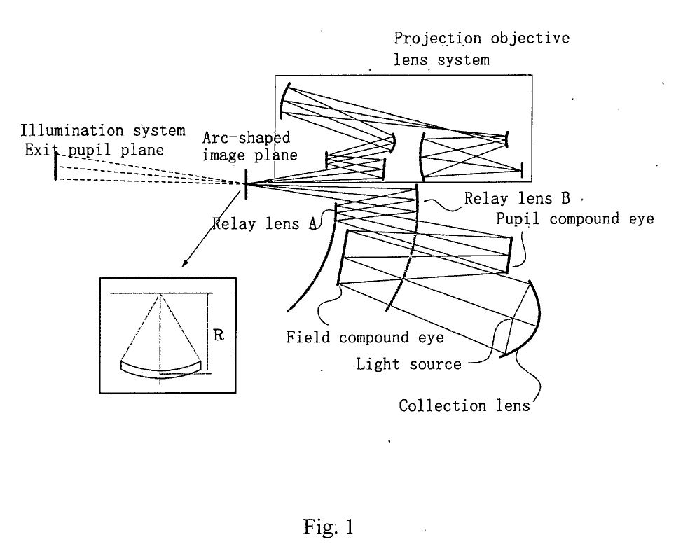

The present invention provides an adjustment and design method of an illumination system matched with multiple objective lenses with respect to an extreme ultraviolet lithography machine, enabling the adjusted illumination system to provide satisfactory illumination for a series of projection objective lenses having the same exposure view field, the illumination system to which the method is applicable comprises a light source, a collection lens, a field compound eye, a pupil compound eye and a relay lens group composed of two quadric surfaces, meanwhile, the first relay lens in the relay lens group, through which emergent ray from the light source passes, is defined as a relay lens A, the second relay lens, through which the emergent ray passes, is defined as a relay lens B, as shown in FIG. 1.

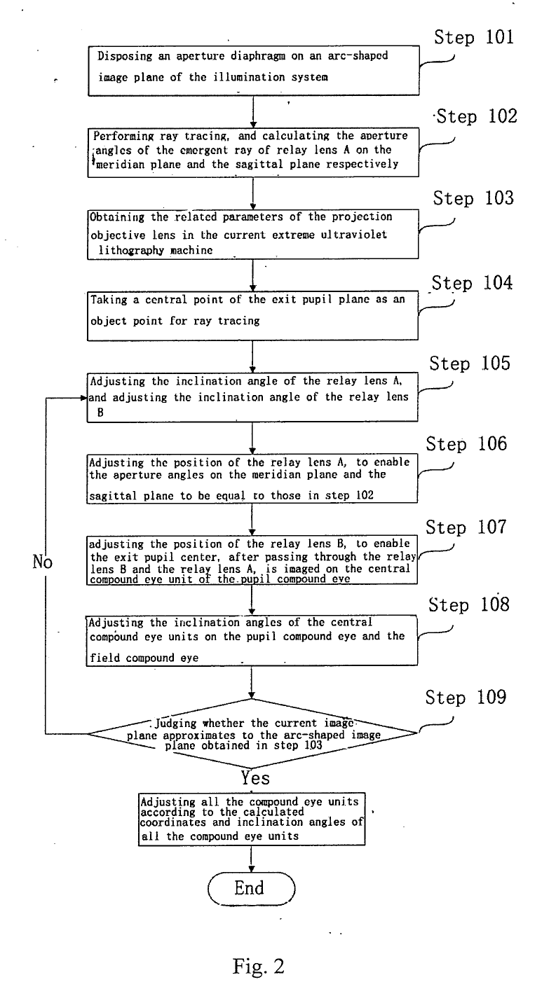

A coordinate system O-XYZ is provided in the embodiment simultaneously, this coordinate system takes a center of a circle of a concentric annulus of the arc-shaped image plane in an initial illumination system as the origin of coordinates 0, and takes the direction of the vector formed from a central point of the exit pupil plane to the origin of coordinates as a positive direction of the Z-axis, takes the direction of the vector formed from a central point of the arc-shaped image plane to the origin of coordinates as a positive direction of the Y-axis, and determines a positive direction of the X-axis with the “right-hand rule”; all the calculation involved in the following steps is carried out under the coordinate system; as shown in FIG. 2, the detailed process of the adjustment method of the present invention is as follows:

before the projection objective lens of the extreme ultraviolet lithography machine is replaced:

At step 101, an aperture diaphragm is disposed on an arc-shaped image plane of the illumination system, and the dimension of the aperture diaphragm and the dimension of the arc-shaped image plane are unified.

Because during actual operation of the illumination system, emergent light beam from the light source converges at the arc-shaped image plane and then is incident on the exit pupil plane, therefore, when this method is implemented by taking the exit pupil plane as an object plane, all emergent ray from the exit pupil plane must also enter a follow-up system after converging on the arc-shaped image plane, thereby guaranteeing the correctness of reverse design thought (the basis of the adjustment method in the present invention is exactly reverse design). Thus, the region corresponding to the arc-shaped image plane is just equivalent to an aperture diaphragm, and the size of this aperture diaphragm is required to be the same as that of the region.

At step 102, by using the exit pupil plane as an object plane, ray tracing is performed, that is, ray tracing is performed by taking the central point of the exit pupil plane as an object point, and the aperture angles of the emergent ray of the relay lens A on the meridian plane and the sagittal plane are calculated respectively.

In this step, ray tracing is the technological means commonly used optical design, which can be realized in optical design software zemax or code V.

After the projection objective lens of the extreme ultraviolet lithography machine is replaced:

At step 103, the related parameters of the projection objective lens in the current extreme ultraviolet lithography machine is obtained, and the parameters are taken as the design indexes of the illumination system, wherein the related parameters include the dimension of the arc-shaped image plane, the incidence angle of the primary ray on the arc-shaped image plane and the numerical aperture on the arc-shaped image plane.

Due to the identical exposure view field of the projection objective lenses to which the present invention is applicable, the dimensions of the arc-shaped image planes of all the projection objective lenses are identical.

The distance from the exit pupil center of the illumination system to the origin Of coordinates is equal to that from the center of a circle of the two concentric circles forming the arc-shaped object plane of the objective lens system to the entrance pupil center of the objective lens system, by a series of adjustment to the illumination system in the following steps, meanwhile, the exit pupil size of the illumination system should be equal to the entrance pupil size of the objective lens system.

At step 104, the exit pupil plane is calculated according to the related parameters, and a central point of the exit pupil plane is taken as an object point for ray tracing. Calculation of the exit pupil plane according to the related parameters in this step is the prior art, and is therefore not described in detail in the present invention.

At step 105, the inclination angle of the relay lens A is adjusted, in order to compensate for the changes of the magnifying power of the field compound eye that results from subsequent adjustment in the illumination system; and the inclination angle of the relay lens B is adjusted, and fine adjustment is carried out on the coordinates Y and Z of the relay lens A simultaneously, in order to compensate for the changes of a central angle corresponding to an arc-shaped light beam that occur due to subsequent adjustment during the process of propagation.

At step 106, the position of the relay lens A is adjusted (namely the coordinates Y and Z of the relay lens A is adjusted), to control the aperture angles of the emergent light beam of the relay lens A in the illumination system on the meridian plane and the sagittal plane simultaneously, and enable the aperture angles to be respectively equal to the aperture angles of the emergent light beam of the relay lens A on the meridian plane and the sagittal plane calculated in the step 102.

At step 107, the position of the relay lens B is adjusted (namely the coordinates Y and Z of the relay lens B is adjusted), so that an exit pupil center, after passing through the relay lens B and the relay lens A, is ensured to be imaged on a central compound eye unit of the pupil compound eye, with the two conditions below being met: 1, the center of a light spot on the central compound eye unit of the pupil compound eye and the center of the central compound eye unit of the pupil compound eye coincide, and 2, the light beam that is incident on the central compound eye unit of the pupil compound eye can be reflected into the field compound eye pupil compound by the central compound eye unit of the pupil compound eye field compound

At step 108, the inclination angles of a pair of central compound eye units on the pupil compound eye and the field compound eye are adjusted, so that the light beam, after passing through the central compound eye unit of the pupil compound eye, can be reflected by the central compound eye unit of the field compound eye, and the light beam, which is reflected by the central compound eye unit of the field compound eye, is perpendicularly incident into the collection lens and then converges at the position of the light source.

At step 109, modeling is carried out by utilizing optical software for judging whether the image plane of the current illumination system approximates to the arc-shaped image plane obtained in the step 103 or not. If so, the coordinates and inclination angles of all the compound eye units in the field compound eye and the pupil compound eye can be calculated by means of ray tracing and the like, so as to complete the adjustment of the illumination system matched with the objective lens system, wherein the method for calculating the coordinates and inclination angles of the compound eye units is the prior art (see the application number: 201210132163.6), which is not described in detail herein, and then all the compound eye units are adjusted according to the calculated coordinates and inclination angles, so as to complete the adjustment of the illumination system; and if not, the steps 105 to 108 are sequentially repeated until the design of the illumination system matched with the objective lens system is completed.

The approximation in the step is to meet the following two conditions: firstly, on the image plane of the current illumination system, the illuminance in the area of the arc-shaped image plane determined in the step 103 accounts for over 80% of the total illuminance of the whole image plane, and secondly, the non-uniformity of the illumination in the area of the arc-shaped image plane determined in the step 103 is 5% or less.

### Embodiment of the Present Invention

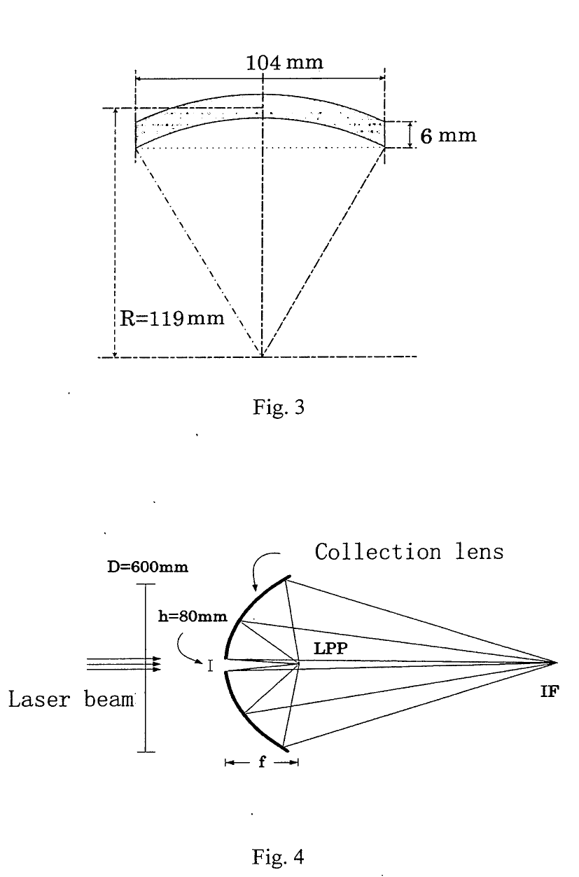

Table 1 shows design indexes for three sets of illumination systems matched with different projection objective lenses, wherein the first set is taken as the design indexes of the initial illumination system, and the other two sets are obtained according to the design of the present invention. Three sets of systems all adopt laser plasma light sources, and the parameters of light source and collection lenses are obtained by calculating the data provided by EUV light source manufacturer Cymer, with their structures shown in FIG. 4. The sizes of the arc-shaped object planes are identical in all the objective lens systems, with their structures shown in FIG. 3. However, the incidence angle of primary ray of the arc-shaped object plane in each objective lens system and the object space numerical aperture are all different, therefore its entrance pupil parameters are also different. Owing to the fact that the incidence angle of the primary ray on the arc-shaped object plane in the extreme ultraviolet lithography objective lens system usually changes between 4.9 degrees to 6 degrees, and the typical values of the object space numerical apertures of the extreme ultraviolet lithography objective lens are 0.0625, 0.075 and 0.0825, in order to show the broad applicability of this method, the incidence angles of the primary ray on the arc-shaped objective planes of the system 1, the system 2 and the system 3 are respectively set as 5.52 degrees, 4.9 degrees and 6 degrees, and their image space numerical apertures are respectively set as 0.0625, 0.075 and 0.0825.

TABLE 1

| Project | System 1 | System 2 | System 3 |
|---|---|---|---|
| Wavelength | 13.5 nm | | |
| Size of the arc-shaped image plane | 104 mm × 6 mm, R = 119 mm | | |
| Parameter of the collection lens | A = 0.888615, b = 0.561265 | | |
| | D = 600 mm, h = 80 mm | | |
| Incident angle of primary ray on the | 5.52° | 6° | 4.9° |
| arc-shaped image plane | | | |
| Numerical aperture on the arc-shaped | 0.0625 | 0.075 | 0.0825 |
| image plane | | | |

For the three sets of illumination systems designed according to the method in the present invention, on the basis of the initial illumination system, variables of the relay lens group parameters in the other two sets of illumination systems are as shown in Table 2. For convenience of illustration, in Table 2, #1 represents the relay lens 1, #2 represents the relay lens 2, and ΔY, ΔZ and Δα represent variables of the coordinate Y, coordinate Z and inclination angle a of the corresponding relay lens respectively. The three sets of illumination systems all can realize various off-axis illumination modes of diode, quadrupole and annular shape, etc. For simplicity and clarity, now the three sets of systems are subjected to property evaluation with diode illumination as the example.

TABLE 2

| Component | | | |
|---|---|---|---|
| parameters | System 1 | System 2 | System 3 |
| ΔY_{#1} | 0 | −25.908 mm | 16.809 mm |
| ΔZ_{#1} | 0 | 43.711 mm | 2.338 mm |
| ΔY_{#2} | 0 | −15.815 mm | −45.646 mm |
| ΔZ_{#2} | 0 | 25.506 mm | 22.981 mm |
| Δα_{#1} | 0 | 0 | −0.55° |
| Δα#2 | 0 | −0.736° | 0.66° |
| Uniformity | 96.64% | 96.71% | 96.47% |
| σᵢₙ~σₒᵤₜ | 0.23-0.9 | 0.23-0.9 | 0.23-0.9 |
| System overall | 3161.7 mm | 3161.7 mm | 3161.7 mm |
| length | | | |

Due to the fact that step-and-scan mode is adopted for extreme ultraviolet lithography, the illumination system of the extreme ultraviolet lithography usually adopts uniformity U of integral illuminance of the arc-shaped image plane in the scanning direction:

$$U = ( 1 - \frac{{E}_{max} - {E}_{min}}{{E}_{max} + {E}_{min}} ) \times 100 \%$$

wherein Eₘₐₓ and Eₘᵢₙ represent the minimum and maximum integral illuminance of the arc-shaped image plane in the scanning direction, respectively. Optical software can be used for ray tracing to accurately evaluate the performance of the systems, after the three sets of illumination systems have been designed. Owing to the size of the laser plasma light source is small enough relative to the illumination system; the point light source can be used for simulating the actual light source. There are 200,000,000 light beams emitted from the point light source, and the performance of the three sets of illumination systems is as shown in table 2. As can be seen from the table, the amount of movement of components in system 2 and system 3 is smaller relative to the overall length of the whole system, and the illumination uniformity of each set of illumination system on the arc-shaped image plane meets the requirement. The result shows that the method in the present invention is effective and feasible.

To sum up, those are only the preferred embodiments of the present invention, and are by no means limiting the scope of protection of the present invention. It will be appreciated that modifications, substitutions and variations of the present invention are covered by the above teachings without departing from the spirit and principle of the present invention.

1. An adjustment and design method of an illumination system matched with multiple objective lenses in an extreme ultraviolet lithography machine, the illumination system to which the method is applied comprising a light source, a collection lens, a field compound eye, a pupil compound eye and a relay lens group; the first relay lens in the relay lens group through which emergent ray from a light source passes being defined as a relay lens A, and the second relay lens through which the emergent ray passes being defined as a relay lens B; characterized in that, the method specifically comprises the following steps:
Before a projection objective lens of the extreme ultraviolet lithography machine is replaced:
Step 101, disposing an aperture diaphragm on the arc-shaped image plane of the illumination system, and unifying the size of the aperture diaphragm and the size of the arc-shaped image plane;
Step 102, taking a central point of an exit pupil plane of the illumination system as an object point for ray tracing, and calculating aperture angles of emergent ray of the relay lens A on a meridian plane and a sagittal plane respectively;
After the projection objective lens of the extreme ultraviolet lithography machine is replaced:
Step 103, obtaining related parameters of the projection objective lens in the current extreme ultraviolet lithography machine, wherein the related parameters include the size of the arc-shaped image plane, the incidence angle of primary ray on the arc-shaped image plane and the numerical aperture on the arc-shaped image plane;
Step 104, calculating the exit pupil plane according to the related parameters, and taking a central point of the exit pupil plane as an object point for ray tracing;
Step 105, adjusting the inclination angle of the relay lens A, in order to compensate for the changes of the magnifying power of the field compound eye that results from subsequent adjustment in the illumination system; and adjusting the inclination angle of the relay lens B, in order to compensate for the changes of a central angle corresponding to an arc-shaped light beam that occur due to subsequent adjustment during the process of propagation;
Step 106, adjusting the position of the relay lens A, to enable the aperture angles of the emergent light beam of the relay lens A on the meridian plane and the sagittal plane to be respectively equal to the aperture angles calculated in the step 102;
Step 107, adjusting the position of the relay lens B, so that an exit pupil center, after passing through the relay lens B and the relay lens A, is imaged on a central compound eye unit of the pupil compound eye, with the two conditions below being met: 1, the center of a light spot on the central compound eye unit of the pupil compound eye and the center of the center compound eye unit of the pupil compound eye coincide, and 2, the light beam that is incident on the central compound eye unit of the pupil compound eye can be reflected into the field compound eye by the center compound eye unit of the pupil compound eye;
Step 108, adjusting the inclination angles of the central compound eye units on the pupil compound eye and the field compound eye, so that the light beam, after passing through the central compound eye unit of the pupil compound eye, can be reflected by the central compound eye unit of the field compound eye, and the light beam, which is reflected by the central compound eye unit of the field compound eye, is perpendicularly incident into the collection lens and then converges at the position of the light source;
Step 109, judging whether the image plane of the current illumination system approximates to the arc-shaped image plane obtained in the step 103 or not, and if so, calculating the coordinates and inclination angles of all the compound eye units in the field compound eye and the pupil compound eye, and adjusting all the compound eye units according to the calculated coordinates and inclination angles, so as to complete the adjustment of the illumination system; and if not, sequentially repeating the steps 105 to 108 until the requirement is satisfied.

2. The adjustment and design method of an illumination system matched with multiple objective lenses in an extreme ultraviolet lithography machine according to claim 1, characterized in that, the approximation in the step 109 is to meet the two conditions below: 1, on the image plane of the current illumination system, the intensity of illumination within the area of the arc-shaped image plane determined in the step 103 accounts for over 80% of the total intensity of illumination of the whole image plane, and 2, the illumination non-uniformity within the area of the arc-shaped image plane determined in the step 103 is less than or equal to 5%.
